(19) United States
(12) Patent Application Publication
(10) Pub. No.: US 2001/0038140 A1
(43) Pub. Date: Nov. 8, 2001

(54) High rigidity, multi-layered semiconductor package and method of making the same

(76) Inventors: Jeffrey A. Karker, Cazenovia, NY (US); Lee B. Max, San Jose, CA (US); Juan L. Sepulveda, Tucson, AZ (US); Kirankumar H. Dalal, North Andover, MA (US); Norbert Adams, Syracuse, NY (US)

Correspondence Address: CALFEE HALTER & GRISWOLD, LLP, 800 SUPERIOR AVENUE, SUITE 1400, CLEVELAND, OH, 44114, US

(21) Appl. No.: 09/758,088

(22) Filed: Jan. 10, 2001

Related U.S. Application Data
(62) Division of application No. 09/544,706, filed on Apr. 6, 2000.

(51) Int. Cl. H01L 21/48

(52) U.S. Cl. 257/666; 438/106

(57) ABSTRACT

The present invention provide a plurality of layered substrates for semiconductor packages. The substrates include, for example, a metal matrix composite layer and at least one carrier layer having a coefficient of thermal expansion and a thermal conductivity greater than the metal matrix composite. In the preferred embodiment, the metal matrix composite includes between approximately 50% to 95% refractory metal with the remainder copper. Suitable carrier layer materials include, for example, copper. So configured, the layered substrates provide improved rigidity and thermal characteristics for matching with ceramic materials.

### FIELD OF THE INVENTION

The invention relates generally to semiconductor devices and packages, and more particularly, to a multi-layered package having high rigidity and improved thermal characteristics.

### BACKGROUND OF THE INVENTION

Since their inception, semiconductor devices have played an important role in the technological development of industries and societies. From the first solid state radio, semiconductor devices have evolved in design and application to contemporary computer systems, cellular telephones, radar systems, medical instrumentation, and household appliances.

Early semiconductor devices were passive and limited to simple junction (i.e., pn junction) devices known as diodes. These simple junction devices, in turn, led to the development of other devices, such as transistors and integrated circuits. These early semiconductor devices were packaged in epoxies or plastics and had only two or three metal leads for electrical connection.

As the art continues to evolve, complex semiconductor devices are now required in many applications. These complex devices must be capable of operating over a broad frequency and power range. For example, cellular telephones and radar systems require semiconductor devices having high frequency and high power capabilities.

Conventional power semiconductor packages are often made from clad metal substrates. Such clad metal substrates are cold worked during their rolling operations. As a consequence of cold working during rolling operations, stresses are induced into the lattice of the metals. After rolling operations, these internal stresses are released by annealing the substrate. However, releasing these internal stresses causes unwanted deformations such as, for example, warping, in the substrates. Current clad metal substrates, such as Cu—Mo—Cu and Ni—Mo—Ni, exhibit the tendency to warp when submitted to temperature cycling or even during the assembly process. Hereinafter, elements that are clad or brazed together shall be denoted by the convention “—” such as, for example, Cu—Mo—Cu and composites such as metal matrix composites shall be denoted the convention “/” such as, for example, Cu/Mo. Table 1 illustrates certain thermal properties for metal clad substrates:

TABLE 1

| | | | | Coefficient |
|---|---|---|---|---|
| | | Thermal | Thermal | of Thermal |
| | | Conductivity | Resistance | Expansion |
| Substrate | Attach. | (W/mK) | θ_{JC} (° C./W) | (ppm/° C.) |
| Configuration | Process | (note 3) | (note 1) | (note 3) |
| 20-20-20 | Cold | 251 | 0.533 | 8.6 |
| Cu—Mo—Cu | Roll | | | |
| (note 2) | | | | |
| 15-30-15 | Cold | 213 | 0.631 | 7.3 |
| Cu—Mo—Cu | Roll | | | |
| 12-36-12 | Cold | 194 | 0.694 | 6.5 |
| Cu—Mo—Cu | Roll | | | |

Note 1:
Values calculated using resistances in a series model for a 0.11″ × 0.10″ die dissipating 30 W.
Note 2: Layered Substrate consisting of 0.020″Cu—0.020″Mo—0.020″Cu.
Note 3: Values determined by Climax Research Services, Wixom, Michigan.

Additionally, as the structural stability of the substrate deteriorates (as described above), the integrity and reliability of other components such as the electronic die, ceramic enclosures such as ring-frames, and other passive components such as capacitors, is compromised. Of particular relevance is that electronic die longevity dramatically decreases when its surrounding package releases inherent mechanical stresses that have been built into it. Accordingly, a method for making a semiconductor substrate and package is highly desirable that does not suffer from the aforementioned defects.

### SUMMARY OF THE INVENTION

The present invention provides layered metal substrates and combination layered metal and ceramic substrates having improved thermal conductivity and low coefficients of thermal expansion. These results are achieved using metals, metal matrix composites, ceramic substrates, and appropriate bonding processes. The substrates produced according to the present invention are characterized by having a low thermal expansion metallic core or constraining layer that has attached thereto one or more metal carrier or spreading layers that are highly thermally conductive and have a higher coefficient of thermal expansion than the constraining layer.

The constraining layer is significant because it limits the expansion of the highly thermally conductive outer carrier layers. In the present invention, the constraining layer most preferably comprises a metal matrix composite that exhibits a higher rigidity compared to other conventional metals. This improved rigidity is a result of the constraining layer's modulus of elasticity in combination with annealing processing temperatures. These differentiating attributes eliminate or significantly minimize warping that would commonly occur for clad metal substrates during subsequent temperature excursions during assembly operations such as die attach, lead attach, ceramic frame attach, etc.

In the most preferred embodiment of the present invention, attachment of the different layers of the substrate is achieved by using either a brazing or fusing process. After brazing or fusing, the layered substrates of the present invention are substantially flat and annealed right out of the furnace. No significant distortion of the crystalline microstructure is imparted, thereby increasing the structural stability during the substrates functional use. This method produces rigid, substantially defect free, non-delaminating substrates of improved thermal conductivity through the z-axis since interfaces among the different layers has been minimized as compared to prior substrates.

According to the present invention, a semiconductor package is provided that has a substrate having at least one constraining layer and at least one or more carrier layers. The constraining layer is preferably made of materials having a low coefficient of thermal expansion when compared to the carrier layers and a good thermal conductivity. The carrier layers are preferably made of materials that have a higher thermal conductivity and a higher coefficient of thermal expansion compared to the constraining layer. Having such characteristics, the constraining layer limits the expansion of the highly thermally conductive carrier layers. In addition thereto, the constraining layer material also preferably exhibits a higher rigidity, as compared to the carrier layers. Improved package rigidity is achieved as a result of the constraining layer's greater strength and hardness when compared to the carrier layers. These differentiating attributes between the constraining layer and the carrier layers significantly minimize and/or eliminate warping that is commonly encountered during subsequent temperature excursions during package assembly operations such as die, lead, ceramic frame, etc., attaching processes.

Materials suitable for the constraining layer preferably include metal matrix composites such as, for example, composites that include refractory metals including copper/tungsten, copper/molybdenum, copper/silicon carbide, beryllia/beryllium, aluminum/silicon carbide (preferably 55 to 75 vol. % silicon carbide), E-MATERIALS™ such as E60 (60 vol. % beryllia and 40 vol. % beryllium), E40 (40 vol. % beryllia and 60 vol. % beryllium) and E20 (20 vol. % beryllia and 80 vol. % beryllium), CuBe/W and other composites or combinations thereof that exhibit an appropriate thermal conductivity and a lower thermal expansion than the highly thermal conductive carrier layers, for example. Other refractory metals suitable for forming metal matrix composites include chromium, niobium, tantalum, vanadium, and titanium. Materials suitable for carrier layers include, for example, copper, silver, gold, aluminum, metallic alloys such as copper silver, beryllium copper, and beryllium nickel, and metal matrix composites such as copper-tungsten and other earlier described metal matrix composites and other similar metals, alloys, and composites that have the appropriate material properties of high thermal conductivity and high electrical conductivity, as compared to the constraining layer.

It is, therefore, an advantage of the present invention to provide layered metal substrates that reduce or eliminate the problem of warping by providing a rigid, more stable base during temperature excursions and assembly and a higher thermal conductivity.

It is, therefore, an advantage of the layered substrates of the present invention to allow for production of structures that are easily plated or etched since copper is a proven and preferred material for such processes. In this regard, the manufacturability of the layered substrates of the present invention is advantageous compared to standard Cu—Mo—Cu or Mo substrates.

It is, therefore, another advantage of the present invention to provide a process that can be applied to previously difficult to join materials which, because thereof, have not been fully utilized. Such materials include, for example, E-MATERIALS™ such as E60 (60 vol. % beryllia and 40 vol. % beryllium), E40 (40 vol. % beryllia and 60 vol. % beryllium) and E20 (20 vol. % beryllia and 80 vol. % beryllium), Cu/Mo, CuBe/W, Cu/SiC, Cu/B₄C, and other metal matrix composite materials that can now be utilized as constraining layer materials and copper, silver, gold, and metallic alloys such as copper silver, beryllium copper, and beryllium nickel, that can now be used as carrier layers.

It is, therefore, another advantage of the present invention to provide the manufacture of layered packages that can be accomplished using subsequent processes or in a single unit operation at the same time as other packaging members such as ceramics and leads are bonded. An assembly made in a single unit operation creates an efficient product in terms of the number of processes and hence cost.

It is, therefore, another advantage of the present invention to provide packages having widespread applications in markets such as, for example, telecommunications, opto-electronics, industrial power, automotive, computer, and similar markets that require efficient heat transfer and high mechanical integrity.

### BRIEF DESCRIPTION OF THE DRAWINGS

In the accompanying drawings which are incorporated in and constitute a part of the specification, embodiments of the invention are illustrated, which, together with a general description of the invention given above, and the detailed description given below, serve to example the principles of this invention.

FIG. 1A through 5B are cross-sectional views of various embodiments of the present invention illustrating the layer and component arrangement of each substrate embodiment.

FIG. 6 is a perspective view of an array of substrates made according to the present invention and suitable for dicing operations.

FIGS. 7A and 7B illustrate one embodiment for a method of making the substrates of the present invention.

FIGS. 8A and 8B illustrate the preferred method of making the substrates of the present invention.

FIGS. 9 through 12 are cross-sectional views of additional embodiments of the present invention illustrating the layer and component arrangement of each substrate embodiment.

FIGS. 13A, 13B, and 13C are scanning electron microscope photographs of a continuous cross-section across a copper/tungsten constraining layer and a copper carrier layer interface made according to the present invention.

FIGS. 14A and 14B are Sonoscan (acoustic) images of a topside of a layered substrate wherein porosity is indicated in white.

### DETAILED DESCRIPTION OF ILLUSTRATED EMBODIMENTS

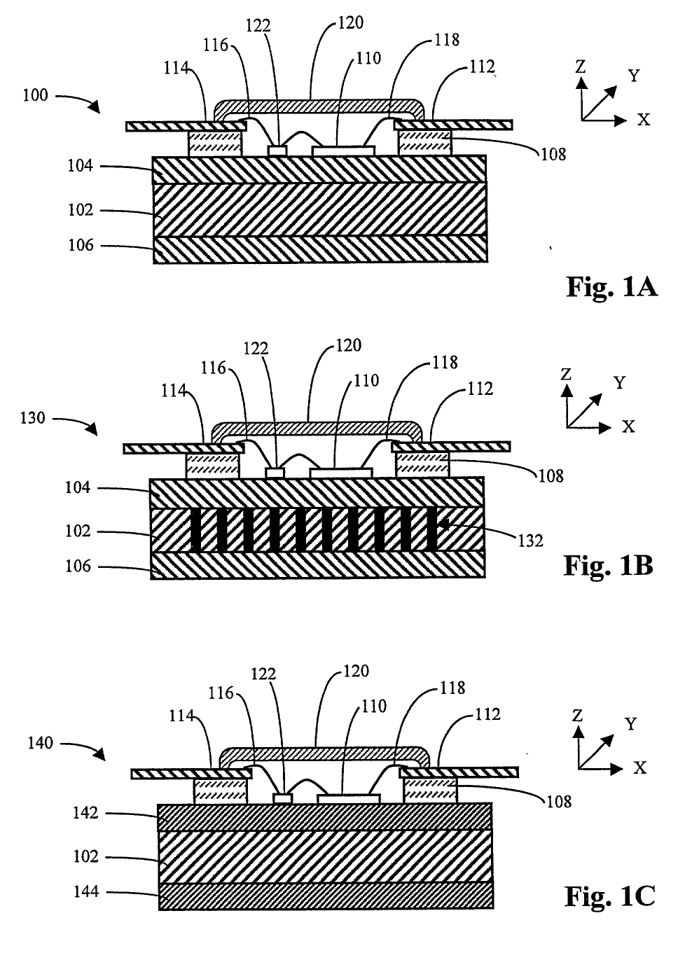

Referring now to the drawings and particularly to FIG. 1A, a sectional view of one embodiment of the present invention is shown. More specifically, the substrate of package 100 has a constraining layer 102 and carrier layers 104 and 106. As described above, the constraining layer 102 has a low coefficient of thermal expansion and high rigidity, as compared to carrier layers 104 and 106.

Materials suitable for constraining layer 102 preferably include metal matrix composites such as, for example, composites that include refractory metals including copper/tungsten, copper beryllium/tungsten and copper/molybdenum, and other composites including copper/silicon carbide, beryllia/beryllium including E-MATERIALS™ such as E60 (60 vol. % beryllia and 40 vol. % beryllium), E40 (40 vol. % beryllia and 60 vol. % beryllium), and E20 (20 vol. % beryllia and 80 vol. % beryllium), aluminum/silicon carbide (preferably 55 to 75 vol. % silicon carbide), and other composites or combinations thereof that exhibit an appropriate thermal conductivity and a lower thermal expansion than the highly thermal conductive carrier layers 104 and 106, for example. Other refractory metals suitable for forming metal matrix composites include chromium, niobium, tantalum, vanadium, and titanium. Materials suitable for carrier layers 104 and 106 include, for example, copper, silver, gold, aluminum, metallic alloys such as copper silver, beryllium copper, and beryllium nickel, and metal matrix composites such as copper-tungsten and other earlier described composites and other similar metals, alloys, and composites that have the appropriate material properties of high thermal conductivity and high electrical conductivity, as compared to the constraining layer 102. The respective carrier-constraining-carrier thickness ratios are preferably in the range of 1:1:1 to 1:5:1, respectively. For example, one suitable thickness ratio for the present invention is 0.012″:0.036″:0.012″ (1:3:1). Additionally, ratios with higher carrier-to-constraining layer thicknesses can be employed depending on the particular application and the desired substrate attributes. The aforementioned thickness ratios shall generally apply to all embodiments described hereinafter.

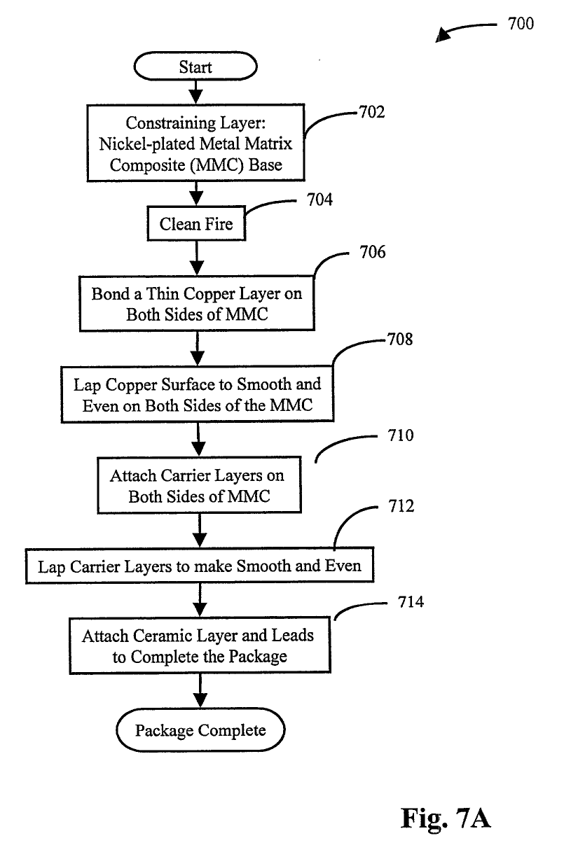

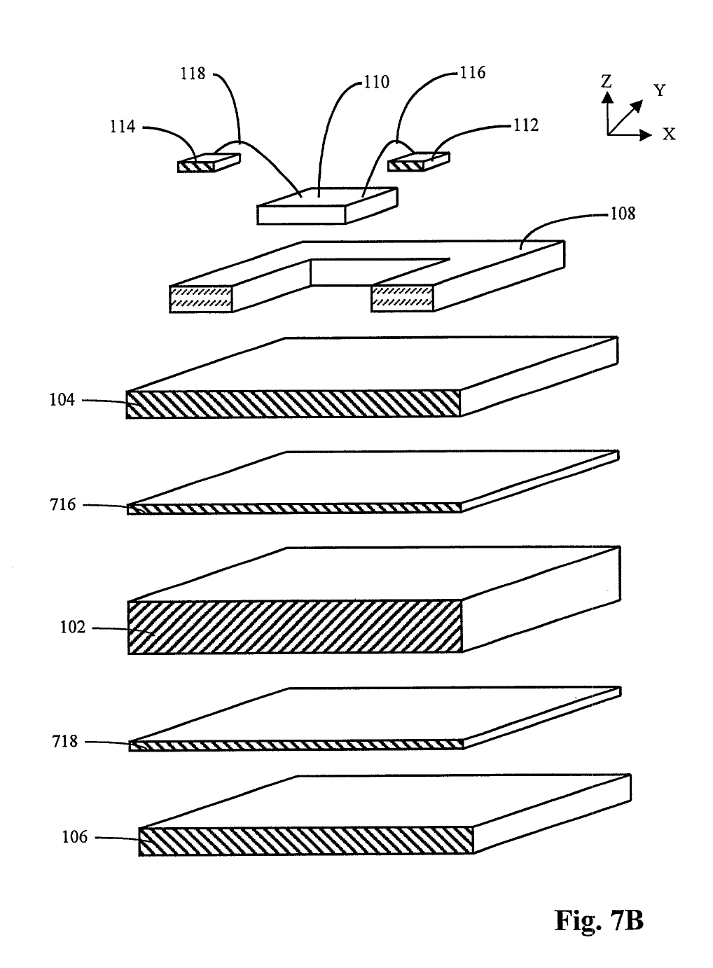

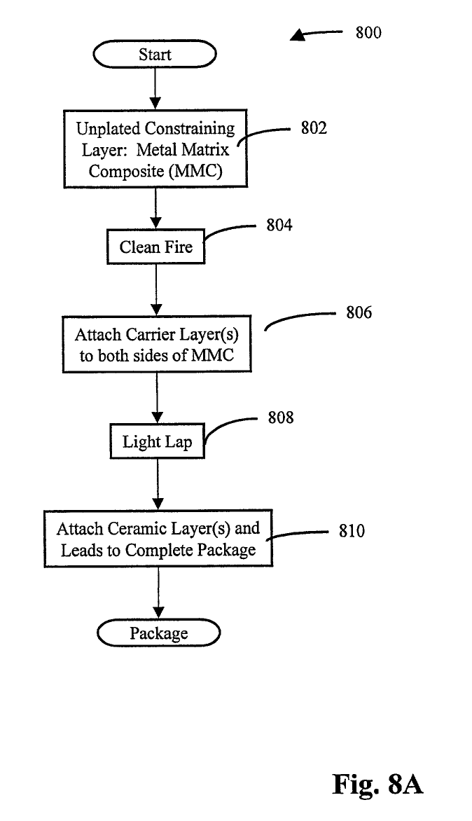

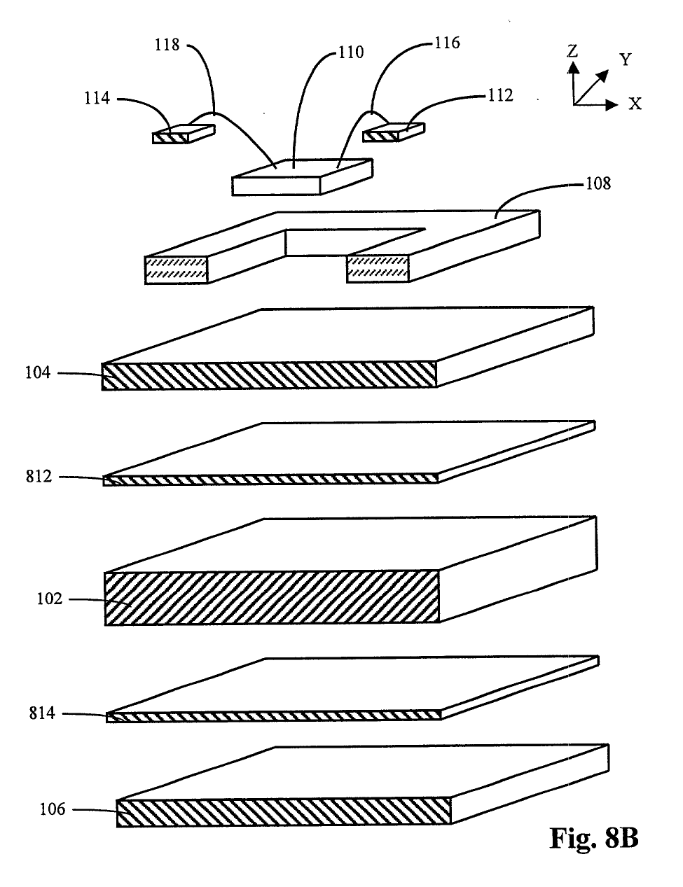

In the embodiment of FIG. 1A, constraining layer 102 is preferably a copper/tungsten metal matrix composite. The copper/tungsten composite of the present invention is preferably approximately 50% to 95% tungsten by weight composition. Most preferably, the copper/tungsten composite of the present invention is about 80% to 90% tungsten. The carrier layers 104 and 106 of package 100 are preferably made of copper. As described in connection with FIGS. 7A through 8B, the carrier layers 104 and 106 are attached to constraining layer 102 via at bond attachment or brazing process of the present invention as discussed further herein.

Table 2 illustrates certain thermal properties such as, for example, thermal conductivity, thermal resistance, and the coefficient of thermal expansion, for the package 100 of the present invention and other packages that can be made according to the present invention (compare to Table 1 cold rolling process data):

TABLE 2

| | | Thermal | | Coefficient |
|---|---|---|---|---|
| | | Conduc- | Thermal | of Thermal |
| Substrate | Attach. | tivity | Resistance | Expansion |
| Configuration | Process | (W/mK) | θ_{JC} (° C./W) | (ppm/° C.) |
| 20-20-20 | Brazing | 308 | 0.452 | 9.61 |
| Cu—Cu15/W85—Cu | | | | |
| 15-30-15 | Brazing | 277 | 0.502 | 8.64 |
| Cu—Cu15/W85—Cu | | | | |
| 15-30-15 | Brazing | 300 | 0.463 | 7.89 |
| Cu—E60—Cu | | | | |
| 20-20-20 | Brazing | 279 | 0.499 | 9.75 |
| Cu—Cu15/Mo85—Cu | | | | |
| 15-30-15 | Brazing | 242 | 0.576 | 8.78 |
| Cu—Cu15/Mo85—Cu | | | | |
| 20-20-20 | DBC | 296 | 0.467 | 8.93 |
| Cu—Cu10/W90—Cu | | | | |
| 15-30-15 | DBC | 261 | 0.528 | 7.82 |
| Cu—Cu10/W90—Cu | | | | |
| 20-20-20 | DBC | 309 | 0.446 | 9.61 |
| Cu—Cu15/W85—Cu | | | | |
| 15-30-15 | DBC | 277 | 0.498 | 8.64 |
| Cu—Cu15/W85—Cu | | | | |
| 12-36-12 | DBC | 260 | 0.530 | 7.14 |
| Cu—Cu15/W85—Cu | | | | |

In Table 2, references to “DBC” and “Brazing” mean Direct-Bond Copper process and brazing, respectively, as described by the present invention in connection with FIGS. 7A through 8B. The thermal conductivity and thermal resistance values of Table 2 were calculated using resistances in a series model for a 0.11″×0.10″ die dissipating 30 Watts. The coefficient of thermal expansion values of Table 2 were calculated using Structural Research and Analysis Corporation's COSMOS/M software for finite element analysis on the same die.

Still referring to FIG. 1A, a metallized ceramic layer 108 such as, for example, alumina metallized with Mo—Mn and plated with Nickel, having a window therein is bonded to carrier layer 104 either by conventional brazing or direct-bond copper process. On metallized ceramic layer 108, copper, alloy-42 (e.g., a nickel-iron alloy), or other metallic leads 112 and 114 are attached via direct-bond copper process or conventional brazing. A semiconductor die or chip 110 and passive component(s) 122 are attached via an attachment method utilizing eutectic bonding, solder, or epoxy, to layer 104. The passive component(s) 122 can be, for example, circuitry with or without a bank of resistors, capacitors, inductors, or combinations thereof. Wire-bonds such as, for example, 116 and 118 provide electrical connection from leads 112 and 114 to the chip 110 and passive component(s) 122. Wire-bonding also provides interconnection between the passive component(s) 122 and semiconductor chip or die 110. A lid 120, which can be plastic, ceramic, metallized ceramic, or metal, is attached to the top of leads 112 and 114 and to the top of ceramic ringframe layer 108 preferably via epoxy or similar process.

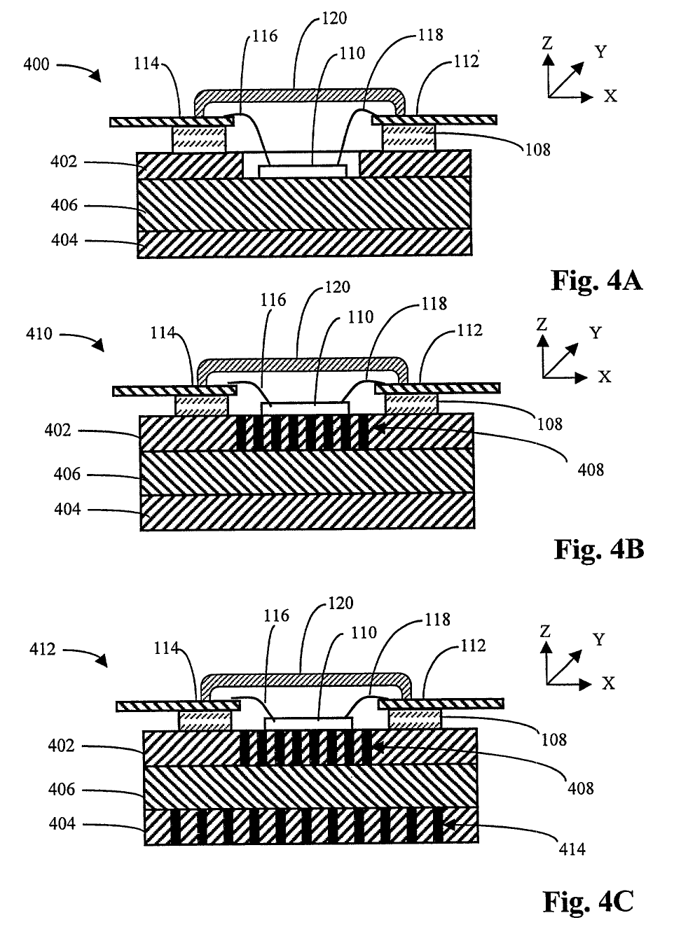

Illustrated in FIG. 1B is an embodiment 130 that is very similar to embodiment 100 of FIG. 1A, except that constraining layer 102 includes a plurality of thermal vias 132 therein. As will be described in more detail in connection with FIGS. 4B and 4C, copper or copper-silver vias in constraining layer 102 improve heat dissipation in the z-axis direction through the constraining layer 102 since the thermal conductivity of copper or copper-silver is greater than that of the constraining layer 102 metal matrix composite such as, for example, a 15 wt. % copper and 85 wt. % tungsten metal matrix composite.

Illustrated in FIG. 1C is an embodiment 140 having a metal matrix composite constraining layer 102 and metal matrix composite carrier layers 142 and 144. In the preferred embodiment, constraining layer 102 can be made of a metal matrix composite being copper 15 wt. % and tungsten 85 wt. % and carrier layers 142 and 144 can be made of a metal matrix composite being copper 85 wt. % and tungsten 15 wt. %. Alternatively, constraining layer 102 can be made of a metal matrix composite being copper 15 wt. % and molybdenum 85 wt. % and carrier layers 142 and 144 can be made of a metal matrix composite being copper 85 wt. % and molybdenum 15 wt. %. As further described above, other combinations are possible so long as the thermal conductivity and thermal expansion of carrier layer 142 and 144 material is greater than that of the constraining layer 102 material.

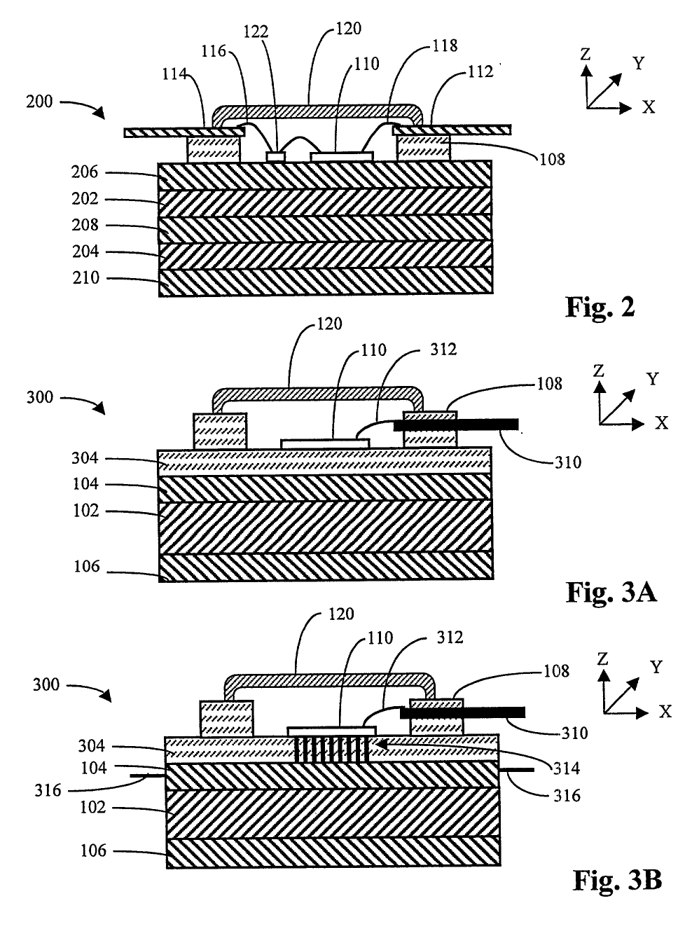

Referring now to FIG. 2, a second embodiment 200 of the present invention showing a multi-layered substrate having two discrete constraining layers 202 and 204 and three discrete high thermal conductivity carrier layers 206, 208, and 210 is shown. The constraining layers 202 and 204 may be made from the same materials as constraining layer 102 of FIG. 1A and include vias as shown in the constraining layer of FIG. 1B. For example, constraining layers 202 and 204 may be made of a copper/tungsten or other metal matrix composite, as described. Carrier layers 206, 208, and 210 may be made of the same materials as described for carrier layers 104 and 106 of FIG. 1A. For example, carrier layers 206, 208, and 210 can be made of copper or other material having a high thermal conductivity and high electrical conductivity, as described. The remaining components of the package such as, for example, metallized ceramic layer 108, chip 110, passive component(s) 122, leads 112 and 114, wire-bonding 116 and 118, and lid 120 are affixed as shown and described earlier.

A third embodiment 300 of the present invention is shown in FIGS. 3A and 3B and is particularly suited for bi-polar and field-effect transistor (FET) chip or die applications. This embodiment is similar to the embodiment 100 of FIG. 1A and further includes a ceramic layer 304, which is attached to carrier layer 104. Layer 304 is preferably made of a ceramic material such as, for example, beryllia (BeO). Beryllia has a coefficient of thermal expansion of approximately 7.8 ppm/° C. and a thermal conductivity of approximately 290 W/mK, which is fairly closely matched to carrier layer 104 when carrier layer 104 is made of, for example, copper. Other ceramics suitable for layer 304 include aluminum-oxide and aluminum nitrate. The advantage of such a configuration is that a good thermal expansion match to the ceramic ringframe layer 108 is achieved in combination with a good thermal conductivity for the die. Additionally, the configuration provides an insulator layer (i.e., ceramic layer 304) that makes the package especially suitable for bipolar semiconductor applications.

The embodiment of FIG. 3B additionally includes thermal and/or ground vias 314 extending from chip or die 110 through carrier layer 304 to carrier layer 104. The process for forming such vias is conventional. The embodiment of FIG. 3B further includes grounding leads 316 that are in electrical and thermal communication with carrier layer 104 and provide the substrate with additional grounding functionality.

Referring now to back to FIGS. 3A and 3B, metallized ceramic layer 108 includes a feed-through 310 formed therein. The feed-through 310 is preferably made of an insulating material such as one or more ceramics and a conducting material such as metal and provides circuit communication between the chip or die 110 and circuitry outside the package. In alternative embodiments, the feed-through 310 is further hermetic, which is desirable if the package is also designed to be hermetic. Suitable sources for feed-through 310 include CIRCUIT PROCESSING TECHNOLOGY, INC., of Oceanside, Calif. and OLIN AEGIS of New Bedford, Mass. One or more wire-bonds 312 are appropriately bonded to the feed-through 310 and the chip or die 110 to complete the circuit communication. The remaining components of the package such as, for example, chip 110 and lid 120, are affixed as shown and described earlier.

FIG. 4A illustrates a fourth embodiment 400 of the present invention having, among other things, two constraining layers wherein one layer is apertured. In particular, the substrate shown in FIG. 4 has two constraining layers 402 and 404 and one highly thermally conductive carrier layer 406. The constraining layers 402 and 404 can be made of the same materials as constraining layer 102 of FIG. 1A. For example, constraining layers 402 and 404 can be made of a copper/tungsten or other metal matrix composites, as described. Carrier layer 406 can be made of the same materials as described for carrier layers 104 and 106 of FIG. 1A. For example, carrier layer 406 can be made of copper or other materials having a high thermal conductivity and high electrical conductivity, as described. Constraining layer 402 has an aperture therein that forms a cavity that accommodates chip 110 such that chip 110 can be affixed directly to carrier layer 406. This configuration improves the stability of ceramic layer 108 because its coefficient of thermal expansion and thermal conductivity can be more close matched to a constraining layer 402 made of, for example, a copper/tungsten metal matrix composite as opposed to a layer made of a material having a high thermal conductivity and high thermal expansion such as, for example, copper. The remaining components of the package such as, for example, ceramic layer 108, chip 110, leads 112 and 114, wire-bonding 116 and 118, and lid 120 are affixed as shown and described earlier.

Illustrated in FIGS. 4B and 4C are embodiments 410 and 412 that also include constraining layers 402 and 404 and carrier layer 406. However, in these embodiments, constraining layer 402 is not apertured and semiconductor 110 is attached directly on the surface thereof. Constraining layer 402 has a plurality of ground and/or thermal vias 408 formed therein. In embodiment 412 of FIG. 4C, constraining layer 404 further includes vias 414 therein that are preferably thermal vias, but can also include ground vias. The vias are preferably made from liquid copper or liquid copper-silver braze during the package manufacturing of FIGS. 7A and 7B. The high thermal conductivity of the vias provide improved heat dissipation in the z-axis direction through the package. For example, in the embodiment 410 of FIG. 4B, the vias 408 provide improved thermal conductivity from the semiconductor chip or die 110 to the carrier layer 406 since copper vias have a higher thermal conductivity than the copper-tungsten constraining layer 402. Similarly, in the embodiment 412 of FIG. 4C, thermal vias 414 provide improved thermal conductivity from carrier layer 406 through constraining layer 404 since copper vias have a higher thermal conductivity than the copper-tungsten constraining layer 404.

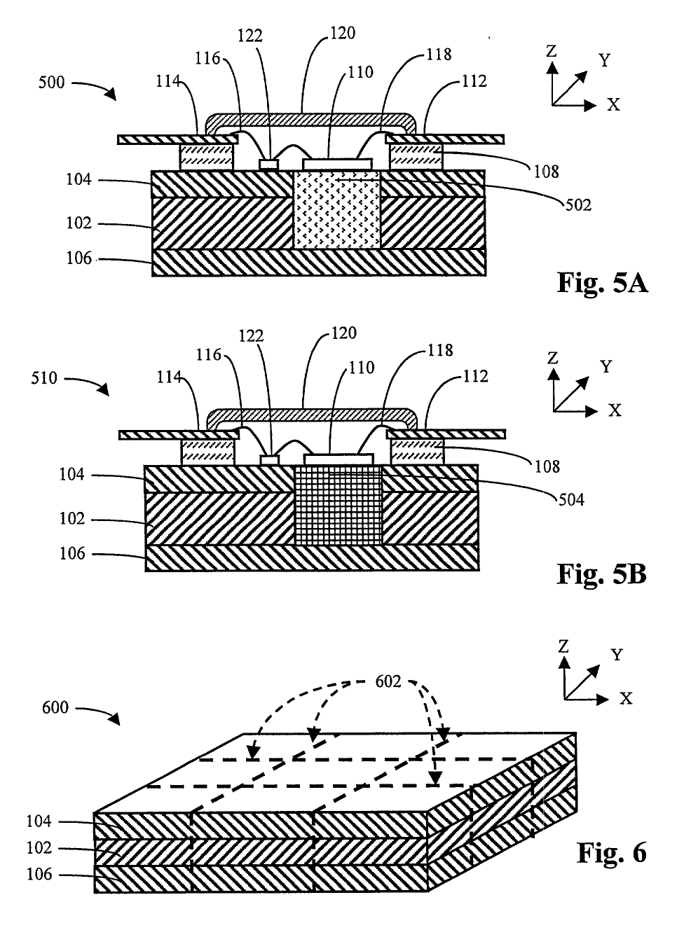

Referring now to FIGS. 5A and 5B, a fifth embodiment 500 of the present invention is shown. More specifically, a Functionally Graded Material (FGM) core 502 and 504 is shown present within the substrate of the package. The purpose of a FGM core is to provide improved z-axis (vertical) heat dissipation from the chip 100 through and out of the substrate. More generally, an FGM metal matrix composite substrate is made of at least two metal compositions and has at least two discrete portions in the X-Y plane: a functional insert or core and a surrounding body. The functional insert or core is closely bonded to the surrounding body. The surrounding body constrains the thermal expansion of the FGM insert or core in the X and Y direction. The expansion of the FGM insert or core in the Z-axis direction is insignificant. Hence, an FGM substrate is characterized by two or more discrete portions each having different thermal properties, electrical and magnetic properties, mechanical properties, and chemical composition. FGM cores and substrates are more fully described in pending U.S. patent application Ser. No. 09/148,126, titled “Functionally Graded Metal Substrates and Process for Making Same” which is hereby fully incorporated by reference.

Suitable FGM core materials for the present invention include copper, silver, copper silver, gold, platinum, beryllium copper, copper/tungsten, copper/molybdemun, silver/tungsten, silver/molybdenum, silver/Invar (Fe—Ni), diamond, and cubic boron-nitride. The FGM core 502 of FIG. 5A is preferably a 50/50 copper/tungsten FGM core, while FIG. 5B illustrates a FGM core 504 that is pure copper. A high thermal conductivity (e.g., 393 W/mK) FGM consisting of 100% pure copper can be incorporated into the layered substrate because all metal layers and components are kept below the melting temperature of copper, insuring their integrity during substrate manufacture. This type of structure provides the maximum thermal dissipation possible when using copper based composites. Hence, copper FGMs are feasible under the present invention.

In either of the embodiments of FIGS. 5A and 5B, chip 110 is attached directly to FGM core 502 and 504, both of which extend through carrier layer 104 and constraining layer 102. The FGM cores 502 and 504 are preferably inserted through a cavity or aperture formed in and extending through these layers. An FGM-cored flange comprised of approximately 50/50 Cu/W surrounded by a single Cu/W (15 wt. % Cu/85 wt. % W) constraining layer has been tested with an Infrared Scan technique on L-DMOS type semiconductor dies having the following length, width, and height dimensions of 0.23″×0.80″×0.060″, respectively, with a Si die measuring 0.035″×0.215″ dissipating 50 watts, and maintaining the temperature of the package at 70° C. throughout the test. It was found that the FGM flanges provide chip 110 with approximately 320 W/mK thermal conductivity and a reduced coefficient of thermal expansion of 7.3 ppm/° C. as compared to copper which provides a thermal conductivity of 393 W/mK but a coefficient of thermal expansion of 17 ppm/° C.

In the case of FGM core 504 being made of copper, as described in the embodiment of FIG. 5B, a thermal conductivity of 393 W/mK can be obtained with a reduced coefficient of thermal expansion of 6 to 7.3 ppm/° C. depending on the composition of the metal matrix composite constraining layer 102 (that is, the FGM core is constrained by the surrounding constraining layer 102).

Referring now to FIG. 6, a perspective view of a multi-layered array 600 useful for producing arrays of packages is shown. More specifically, array 600 is based on embodiment 100 of FIG. 1A and includes constraining layer 102 and carrier layers 104 and 106. Dice lines 602 are illustrated in dashed form to indicate where the array can be diced to provide individual substrates. While array 600 has been shown illustrating the substrate of FIG. 1A, the array 600 can easily be applied to or modified in accordance with the substrate embodiments of FIGS. 2 through 5B.

Referring now to FIGS. 7A and 7B, the one method for making the multi-layered substrate and package of the present invention will be discussed. The process starts in step 702 where a constraining layer made of a nickel-plated metal matrix composite 102 is provided. The constraining layer can be made by the processes as taught by Jech et al. in U.S. Pat. Nos. 5,686,676 and 5,826,159, which are hereby fully incorporated by reference. In step 704, the constraining layer 102 is clean fired in a preferably reducing, neutral, or combination, atmosphere at a temperature of approximately 800° C. to 1200° C. In step 706, thin copper layers 716 and 718, which range in thickness from approximately 0.0005″ to 0.002″, are fused to the top and bottom sides of constraining layer 102 in either a reducing, neutral, or combination environment and at a temperature of between approximately 800° C. to 1200° C.

In step 708, the thin copper layers 716 and 718 are lightly lapped preferably on an abrasive wheel to make the copper layer thickness substantially uniform and substantially free of any burrs and debris. At step 710, carrier layers 104 and 106 are attached as shown to both sides of constraining layer 102. The thickness of carrier layers 104 and 106 is dependent upon the desired thickness ratios of constraining layer 102 and carrier layers 104 and 106 and can range widely depending on the desired thermal conductivity and rigidity (See, for example, Table 2 (above) for ratios and thermal conductivity values). Carrier layers 104 and 106 are preferably attached to both sides of constraining layer 102 using a Direct Bond Copper (DBC) process at a temperature above 1065° C. for a few seconds to several minutes, as taught by Cusano, et al. in U.S. Pat. No. 3,994,430 which is hereby fully incorporated by reference.

In step 712, carrier layers 104 and 106 are cleaned by lightly lapping to make the surfaces thereof substantially uniform and substantially free of any burrs and debris. At step 714, metallized ceramic layer 108 and leads 112 are attached as described earlier by conventional processes. At this point the package is substantially complete and ready to accept chip or die 110, any passive component(s) 122, appropriate wire-bonding 116 and 118, and lid 120.

Referring now to FIGS. 8A and 8B, a flowchart 800 of the preferred method of making the package(s) of the present invention is illustrated. The process commences in step 802 with an unplated constraining layer 102 made of a metal matrix composite (MMC) material, as previously described. In step 804, the constraining layer 102 is clean fired in a reducing, neutral, or combination atmosphere at a temperature of approximately 800° C. to 1200° C. In step 806, carrier layers 104 and 106 are attached to the constraining layer 102 preferably by using solder or braze materials such as copper/silver preforms 812 and 814 at temperatures preferably ranging from about 280° C. to about 900° C. in either nitrogen (N₂), hydrogen (H₂), or a combination of the two. Other preform materials such as, for example, lead/tin, and other suitable gases such as, for example, argon, oxygen and other compatible gases or mixtures thereof, may also be used.

As described in connection with FIGS. 7A and 7B, the thickness of carrier layers 104 and 106 is dependent upon the desired thickness ratios of constraining layer 102 and carrier layers 104 and 106 and can range widely depending on the desired thermal conductivity and rigidity (See, for example, Table 2 (above) for ratios and thermal conductivity values). In step 808, carrier layers 104 and 106 are cleaned by lightly lapping to make the surfaces thereof substantially uniform and substantially free of any burrs and debris. At step 810, metallized ceramic layer 108 and leads 112 and 114 are attached as described earlier by conventional processes. At this point the package is substantially complete and ready to accept chip or die 110, passive component(s) 122, appropriate wire-bonding 116 and 118, and lid 120. In either embodiments of FIGS. 7A and 8A, the metal deposition of for example, carrier layers 104 and 106 and preform layers 812 and 814, can be achieved by many means such as additive plating, printing, chemical vapor deposition, cladding, diffusion bonding or by other processes.

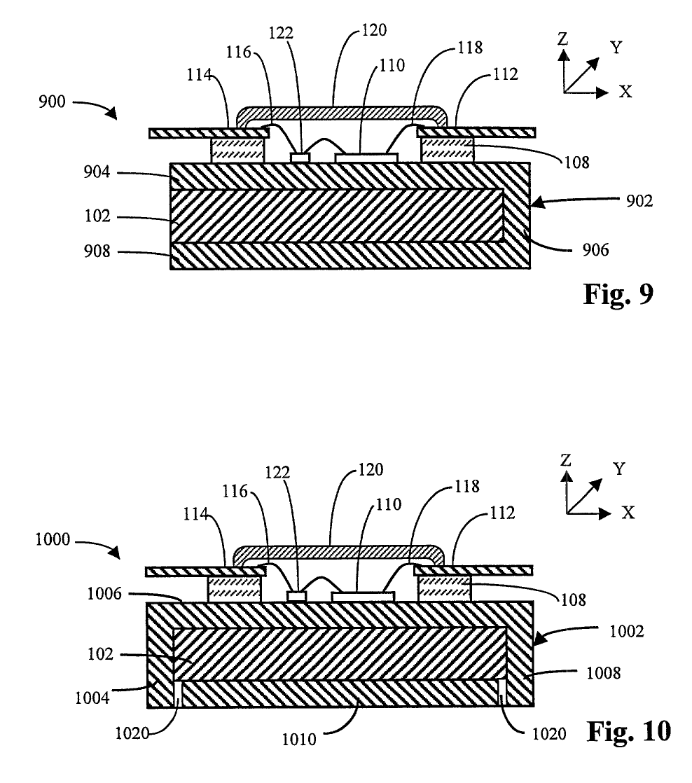

Illustrated in FIG. 9 is another embodiment 900 of the present invention. In particular, the package has constraining layer 102 enveloped by an inverted “C” shaped carrier layer 902. Carrier layer 902 has top and bottom portions 904 and 908, respectively, and side portion 906. Carrier layer 902 can be made of the same materials as carrier layers 104 and 106 of FIG. 1A, which include, for example, copper. Carrier layer 902 functions similar to a very large thermal via on the edge of the constraining layer 102 base by transferring heat generated by chip or die 110 and passive component(s) 122 from the carrier layer top portion 904 to side portion 906 and on to bottom portion 908 for further transfer away from the package. Carrier layer 902 also provides improved electrical conductivity for grounding purposes due to its relative large area and volume. In the preferred embodiment, the constraining layer 102 is approximately at least twice the thickness of carrier layer 902 (i.e., the thickest of any of the top, bottom, and side portions 904, 906, and 908, respectively.)

The package of FIG. 9 is generally made according to the same process(es) described earlier (See FIGS. 7A-8B). In the case of carrier layer 902 being a single piece of material such as, for example, copper, carrier layer is, in steps 710 and 806 of FIGS. 7 and 8, respectively, coined into a sleeve that is appropriated situated around constraining layer 102 so as to provide carrier layer 902 with the desired shape and contact with constraining layer 102. In the case of carrier layer 902 being three or more discrete pieces of material corresponding to top, bottom, and side portions 904, 906, and 908, respectively, these portions are assembled as earlier described for either brazing or DBC attachment to constraining layer 102.

FIG. 10 illustrates an embodiment 1000 of a package similar to that of FIG. 9, except that constraining layer 102 is wrapped on at least four sides and at most all sides by carrier layer 1002. Carrier layer 1002 has side portions 1004 and 1008 and top and bottom portions 1006 and 1010, respectively. Carrier layer 1002 can be made of the same materials as layers 104 and 106 of FIG. 1A such as, for example, copper. To improve manufacturability, bottom portion 1010 may be a discrete layer attached as shown forming clearance slots 1020. So formed, surrounding layer 1002 provides improved thermal and electrical conductivity due to its relatively large volume and area. Heat generated by chip or die 110 and passive component(s) 122 is transferred from top portion 1006 to side portions 1004 and 1008 and bottom portion 1010.

The package of FIG. 10 is also generally made according to the same process(es) as described earlier (See FIGS. 7A-8B). As described in connection with FIG. 9, the wrap-around carrier layer 1002 can, in the case of a single piece of material, be coined around constraining layer 102 via a sleeve. In the case of the wrap-around carrier layer 1002 being four or more discrete pieces of material corresponding to top, bottom, and left and right side portions 1006, 1010, 1004, and 1008, respectively, these portions are appropriately assembled as earlier described by either brazing or DBC attachment to constraining layer 102.

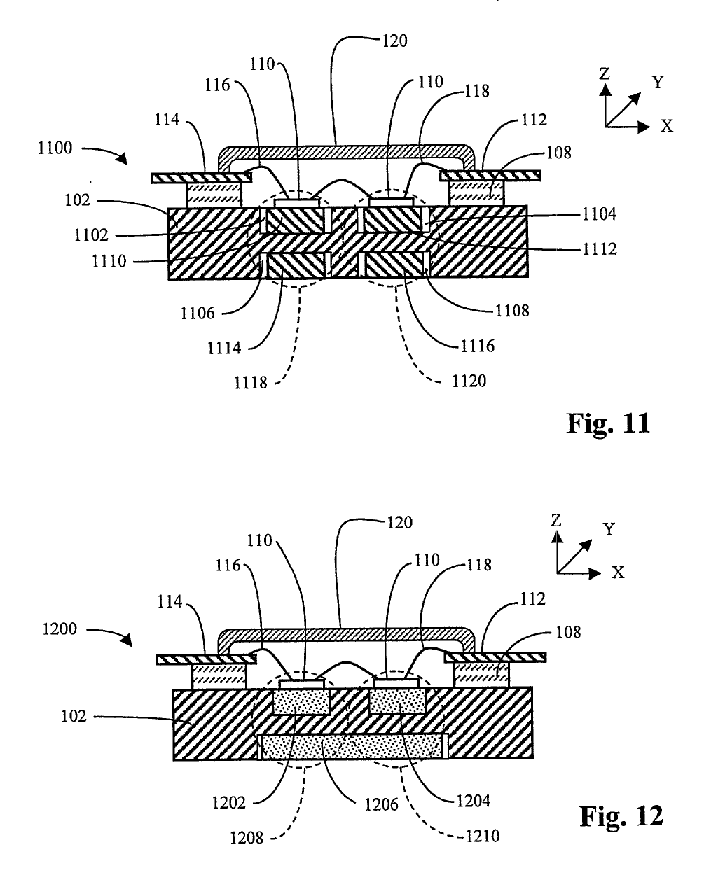

Referring now to FIG. 11, an embodiment 1100 of the present invention having two localized layered substrate portions 1118 and 1120 is shown. While two localized layered substrate portions are shown, the package is not limited to two and may generally include one or more of such portions. The localized layered substrate portions 1118 and 1120 are formed in combination with constraining layer 102. More specifically, constraining layer 102 has cavities 1102, 1104, 1106, and 1108 formed therein via, for example, computer numerical control (CNC) or conventional machining. Carrier layers 1110, 1112, 1114, and 1116 are positioned within cavities 1102, 1104, 1106, and 1108, respectively and attached to constraining layer 102 according to the earlier described process(es) (See FIGS. 7A through 8B). Carrier layers 1110, 1112, 1114, and 1116 are made of the same materials as carrier layers 104 and 106 of FIG. 1A such as, for example, copper, and function the same as the aforementioned layers within the localized layered substrate portions 1118 and 1120.

So fabricated, the carrier layers 1110, 1112, 1114, and 1116 are only constrained by their surface bond to constraining layer 102. That is, in the X-Y plane as shown in FIG. 11. In localized layered substrate portion 1118, the preferred thickness ratios of carrier layer 1110, constraining layer 102, and carrier layer 1114, when composed of copper, copper-tungsten, and copper, respectively, are between 1:1:1 and 1:5:1. Similar ratios apply to carrier layer 1112, constraining layer 102, and carrier layer 1116 within localized layered substrate 1120. As described earlier, when constraining layer 102 made of a copper/tungsten composite, the integrity of metallized ceramic layer 108 is especially improved due to the close match in thermal conductivity and expansion between the copper/tungsten constraining layer 102 and the metallized ceramic layer 108. As evident from FIG. 1A, localized layered substrates portions 1118 and 1120 are similar to the substrate structure shown therein, except that they are localized rather encompassing the entire substrate.

Illustrated in FIG. 12 is an embodiment 1200 of a package having localized layered substrate portion 1208 and 1210. Similar to the embodiment of FIG. 11, the localized layered substrate portions 1208 and 1210 are formed in combination with constraining layer 102 and include FGM cores 1202, 1204, and 1206. FGM cores 1202, 1204, and 1206 are inserted into cavities formed in constraining layer 102. The cavities in constraining layer 102 are formed via CNC or conventional machining. The advantage offered by the package of embodiment 1200 is that the FGM cores 1202 and 1204 are constrained from expansion in the X-Y plane by constraining layer 102. This improves the integrity of metallized ceramic layer 108 since its thermal characteristics are closely matched with constraining layer 102, especially when the ceramic layer 108 is made of metallized alumina and constraining layer 102 is made of a copper/tungsten composite. The FGM cores 1202, 1204, and 1206 can be made of the same material as FGM cores 502 or 504 of FIGS. 5A and 5B, respectively.

Having described the present invention in detail, an example of a layered structure substrate base made according to the preferred embodiment of FIGS. 8A and 8B using a preferred 1:3:1 ratio of Cu:Cu/W:Cu will now be discussed.

More specifically, a plurality of layered substrate bases were made by reducing 0.060″ thick Cu/W base constraining layer (180 W minimum thermal conductivity) to a final thickness of 0.035″. The Cu/W constraining layer was clean fired at 1200° C. in hydrogen (H₂). The carrier layers 104 and 106 were made of copper shims having a thickness of 0.012″ and the same length and width dimensions and shape as the Cu/W constraining layer 102. Two 0.0005″ thick copper-silver eutectic alloy braze preforms 812 and 814 with length and width same as the Cu/W constraining layer 102 were employed as brazing agents. The input materials described above were stacked together in the following configuration as shown in FIG. 8B:

1. 0.012″ thick copper carrier layer 104

2. 0.0005″ thick Copper-silver preform 812

3. 0.035″ thick copper/tungsten constraining layer 102

4. 0.0005″ thick copper-silver preform 814

5. 0.012″ thick copper carrier layer 106.

The assembled stack up was placed in a graphite fixture and sufficient pressure (i.e., 2 in.-lb torque) was applied to make sure there was no movement of any of the materials in the stack while it is going through the furnace. The assembly was brazed together at 850° C. in 25% hydrogen (H₂) and 75% nitrogen (N₂) atmosphere. The bases were then taken out of the fixture and used for making the packages.

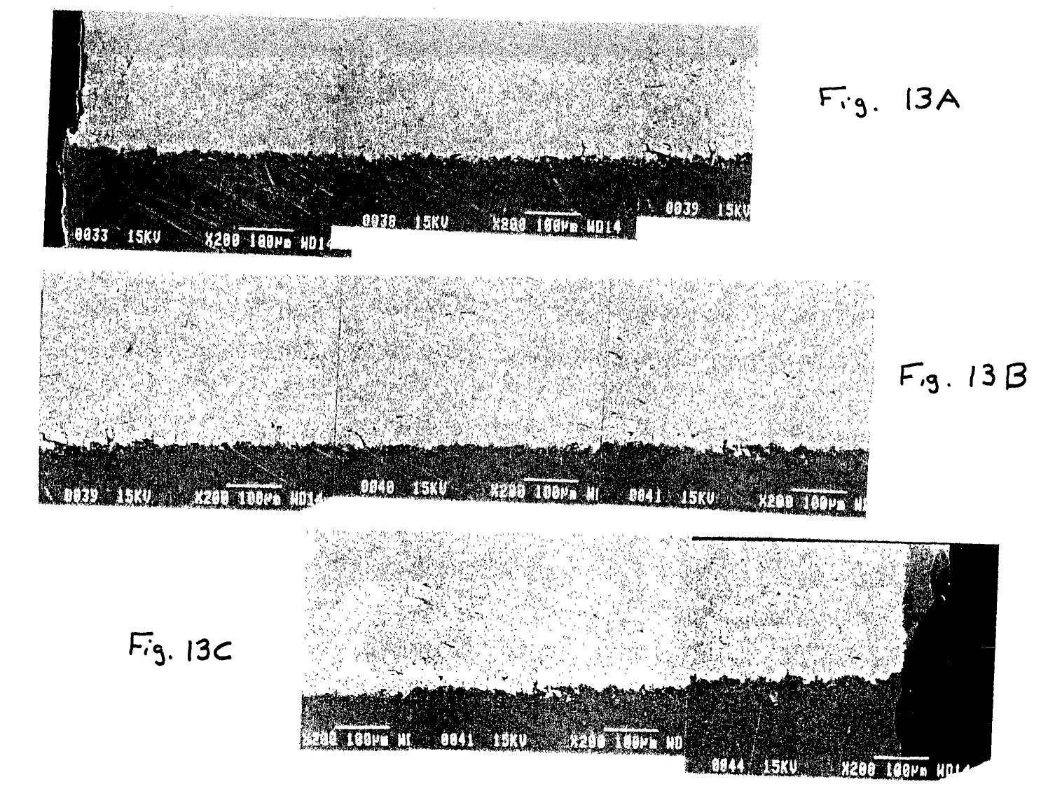

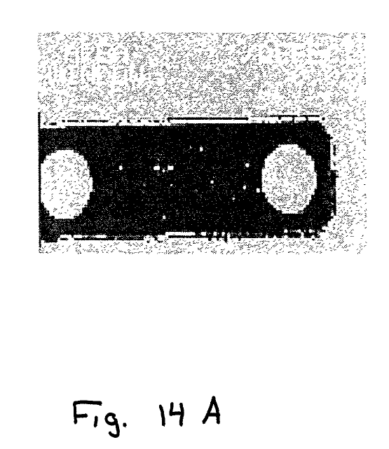

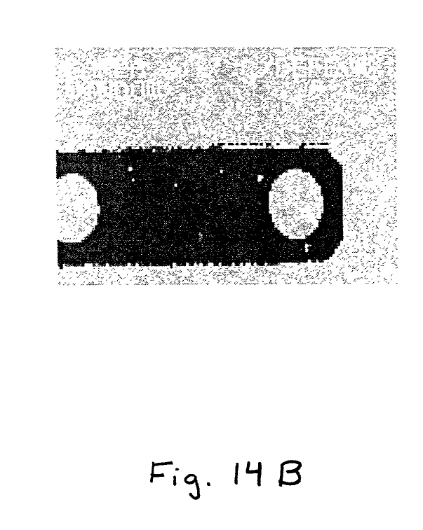

The layered structure bases were evaluated for the integrity of the interfaces between the copper and Cu/W using an acoustic wave technique using Sonoscan equipment as well as a scanning electron microscope (SEM) technique using cross-sections of the substrate layer interfaces. FIGS. 13A, 13B, and 13C are SEM photographs showing void-free continuous cross-sections from left to right of a copper/tungsten constraining layer (the darker layer) and copper carrier layer (the lighter layer) interface. FIGS. 14A and 14B are Sonoscan images of a topside view of a substrate of the present invention showing 99.9% to 100% bond between the two copper carrier layers and the copper/tungsten constraining layer (See FIG. 1A for representative cross-sectional view). In the images, porosity is indicated in white.

In addition, thermal diffusivity of the substrate was also measured using a laser flash technique. The thermal diffusivity data is given below in Table 3 for layer substrates of the present invention having plated and unplated Cu/W, conventional Cu/W bases, and conventional Cu—Mo—Cu substrates with comparable overall thicknesses.

TABLE 3

| | Layered Substrate: | Layered Substrate: | | |
|---|---|---|---|---|
| | Ni Plated Cu/W | UnPlated Cu/W | Cu/W | Cu—Mo—Cu |
| | constraining layer | constraining layer | constraining | layered |
| | (.012″Cu—.035″Cu/ | (.012″Cu—.035″Cu/ | layer alone | substrate |
| | W(15/85)—0.12″Cu) | W(15/85)—0.12″Cu) | (.60″Cu/W(15/85)) | (.02″Cu—.02″Mo—.02″Cu) |
| Thermal | 0.711 | 0.738 | 0.593 | 0.582 |
| Diffusivity | | | | |
| (cm²/sec) | | | | |
| Thermal | 221 | 229 | 163 | 181 |
| Conductivity | | | | |
| (W/mK) | | | | |

Packages were formed using a Mo—Mn metallized and nickel plated ceramic window, alloy-42 leadframe and copper silver braze preforms of 0.00″ thickness. The packages were plated with 100-250 micro-inches of nickel and 100 micro-inches (min) of gold. The same package making procedure was used to make packages from standard Cu/W bases as well as Cu—Mo—Cu (1:1:1) based packages for comparison testing. Ten packages from each group were used to perform the following tests:

A. Thermal Resistance θ_{jc} measurements using an L-DMOS semiconductor die attached to the package and an Infrared scan technique. The lower the thermal resistance value the better the performance.

B. Camber and Flatness measurements after the assembly.

C. Ceramic cracking after bolt down and after thermal cycling through −65° C./+150° C. (i.e., MIL-STD 883 test method 1010.7).

The data for the above test is provided in the Table 4 below.

TABLE 4

| | | Layered | | |
|---|---|---|---|---|
| | Layered | Substrate: | Cu/W | |
| | Substrate: Ni | UnPlated | con- | |
| | Plated Cu/W | Cu/W | straining | Cu—Mo—Cu |
| | constraining | constraining | layer | layered |
| Test | layer | layer | alone | substrate |
| Flatness (in) | 0.00015- | 0.00015- | 0.00015- | 0.00041- |
| | 0.00071 | 0.00071 | 0.00071 | 0.00068 |
| Camber | Mixed | Mixed | Mixed | Concave |
| Direction | | | | |
| θ_{jc} (° C./W) | 0.92 | 1.06 | 1.28 | 0.9 |
| Ceramic | | | | |
| Cracking Bolt | | | | |
| Down Test | | | | |
| 1 in-lb torque | No cracks | No cracks | No cracks | 9 of 10 pcs |
| | | | | cracked |
| 6 in-lb torque | No cracks | No cracks | No cracks | 9 of 10 pcs |
| | | | | cracked |
| After 1000 | No cracks | No cracks | No cracks | 10 of 10 |
| cycles | | | | pcs cracked |
| (package | | | | |
| bolted down to | | | | |
| Al plate) | | | | |

A number of conclusions can be drawn from Table 4. The thermal performance θ_{jc} indicates that packages made according to the present invention resulted in lower thermal resistances, as compared to conventional Cu/W based packages. Additionally, the thermal resistance θ_{jc} performance indicates that of the packages made according to the present invention, using a nickel plated Cu/W constraining layer reduces IR performance by 10%. On this basis, the preferred method of fabricating the present invention is with a Cu/W constraining layer without nickel plating. However, in certain applications, nickel plating may be acceptable or even desirable. The thermal resistance θ_{jc} performance of the layered substrates of the present invention having unplated Cu/W constraining layers is very nearly the same as conventional 1:1:1 Cu—Mo—Cu substrates. However, it is of critical significance that the mechanical rigidity of layered substrates of the present invention is significantly better as evidenced by the combination of camber and flatness observations and the ceramic cracking data in the “bolt down” test, as well as in the temperature cycling test.

It is clearly shown, via the data in Table 4, that in normal electronic packaging applications, packages made from layered substrates of the present invention having bases or constraining layers without nickel plating have 29% better thermal performance (IR) than the conventional Cu/W based packages. Hence, the packages of the present invention are more preferable over conventional 1:1:1 Cu—Mo—Cu based packages because of the above-described qualities and characteristics and because such packages meet the reliability requirements of an electronic package as specified by MIL-STD-883, method 1010.7, condition “C”.

So configured, the present invention is suitable to a plurality of applications including, high-power RF-microwave-millimeter wave amplifier packages for telecommunication transmitters and receivers, high-power commercial and military AC/DC inverter modules, DC/DC converters, high-output commercial and military power supplies, high-reliability hermetic packages, switching applications, microprocessor packages, and mounts and submounts for diode lasers. However, the applications are not limited to just ceramic to metal packages in the electronics markets since the process could also be used by any markets or applications where metal to metal and metal to ceramic bonding thereof needs to be accomplished or enhanced. For example, the layered substrates of the present invention can also be used as cores for coefficient of thermal expansion (CTE) modifying and rigidizing other organic laminates such as, for example, printed-circuit boards (PCB's). Yet another use of the layered substrates of the present invention includes the manufacturing of structures of different geometry such as blocks, large heat-sinks, tubes, and large sheets and foils. The layered structures of the present invention can also be used as structural rigidizers for large electronics assemblies, subassemblies and SEM-E boards, and boxes as typically found in some commercial applications but more commonly found in aerospace and defense applications.

While the present invention has been illustrated by the description of embodiments thereof, and while the embodiments have been described in considerable detail, it is not the intention of application to restrict or in any way limit the scope of the appended claims to such detail. Additional advantages and modifications will readily appear to those skilled in the art. For example, more of less layers in accord with the present invention may be stacked in order to further increase the physical dimensions of the hermetic seal, the planar geometry of the material layers may be modified so as to create rectangular, cylindrical, triangular, and etc., assemblies. Therefore, the invention, in its broader aspects, is not limited to the specific details, the representative apparatus, and illustrative examples shown and described. Accordingly, departures may be made from such details without departing from the spirit or scope of the applicant's general inventive concept.

We claim:

1. A substrate for packaging a semiconductor wherein at least a portion of the substrate comprises:
(a) metal matrix composite having a first and a second side, the metal matrix composite comprising a copper/refractory metal composite having a composition of approximately between 50 wt. % and 95 wt. % refractory metal;
(b) a first carrier layer having a coefficient of thermal expansion and thermal conductivity greater than the metal matrix composite and attached to the first side of the metal matrix composite; and
(c) a second carrier layer having a coefficient of thermal expansion and thermal conductivity greater than the metal matrix composite and attached to the second side of the metal matrix composite.

2. The substrate of claim 1 wherein the first carrier layer comprises copper.

3. The substrate of claim 1 wherein the second carrier layer comprises copper.

4. The substrate of claim 1 wherein the refractory metal is selected from the group consisting of tungsten and molybdenum.

5. The substrate of claim 1 further comprising a second metal matrix composite attached to the second carrier layer.

6. The substrate of claim 5 further comprising a third carrier layer attached to the second metal matrix composite.

7. The substrate of claim 1 wherein the refractory metal is selected from the group consisting of tungsten, molybdenum, chromium, niobium, tantalum, vanadium, titanium.

8. The substrate of claim 1 further comprising a ceramic layer attached to the first carrier layer.

9. The substrate of claim 8 wherein the ceramic layer is selected from a group consisting of beryllium-oxide (BeO), aluminum-oxide, and aluminum nitrate.

10. The substrate of claim 8 wherein the ceramic layer comprises one or more vias.

11. The substrate of claim 1 further comprising a functionally graded material core.

12. The substrate of claim 11 wherein the functionally graded material core is selected from a group consisting of copper, silver, copper silver, gold, platinum, beryllium copper, copper/tungsten, copper/molybdemun, silver/tungsten, silver/molybdenum, silver/Invar, diamond, and cubic boron-nitride.

13. The substrate of claim 1 wherein the first carrier layer comprises an aperture.

14. The substrate of claim 13 wherein the metal matrix composite comprises an aperture.

15. The substrate of claim 14 further comprising a functionally graded material within the aperture of the first carrier layer.

16. The substrate of claim 14 further comprising a functionally graded material within the aperture of the first carrier layer and the metal matrix composite.

17. A substrate for a semiconductor package wherein at least a portion of the substrate comprises:
(a) a copper layer having a first and second side;
(b) a first metal matrix composite layer attached to the first side of the copper layer; and
(c) a second metal matrix composite layer attached to the second side of the copper layer.

18. The substrate of claim 17 wherein the first metal matrix composite comprises a copper/refractory metal composite having a composition of approximately between 50 wt. % and 95 wt. % refractory metal.

19. The substrate of claim 18 wherein the second metal matrix composite comprises a copper/refractory metal composite having a composition of approximately between 50 wt. % and 95 wt. % refractory metal.

20. The substrate of claim 18 wherein the refractory metal is selected from the group consisting of tungsten and molybdenum.

21. The substrate of claim 19 wherein the refractory metal is selected from the group consisting of tungsten and molybdenum.

22. A substrate for a semiconductor package wherein at least a portion of the substrate comprises:
(a) a metal matrix composite having a first side and a second side;
(b) a first layer having a functionally graded material core attached to the first side of the metal matrix composite; and
(c) a second layer having a functionally graded material core attached the second side of the metal matrix composite.

23. The substrate of claim 22 wherein the metal matrix composite comprises a copper/refractory metal composite.

24. The substrate of claim 23 wherein the copper/refractory metal composite comprises approximately between 50 wt. % and 95 wt. % refractory metal.

25. The substrate of claim 23 wherein the refractory metal comprises a metal selected from the group consisting of tungsten, molybdenum, chromium, niobium, tantalum, vanadium, titanium.

26. The substrate of claim 22 wherein the functionally graded material core is selected from the group consisting of: copper, silver, copper silver, gold, platinum, beryllium copper, copper/tungsten, copper/molybdemun, silver/tungsten, silver/molybdenum, silver/Invar, diamond, and cubic boron-nitride.

27. The substrate of claim 22 wherein the first side of the metal matrix composite comprises at least one cavity.

28. The substrate of claim 27 wherein the first functionally graded material core is attached to the metal matrix composite through the at least one cavity in the first side of the metal matrix composite.

29. The substrate of claim 22 wherein the second side of the metal matrix composite comprises at least one cavity.

30. The substrate of claim 29 wherein the second functionally graded material core is attached to the metal matrix composite through at least one cavity in the second side of the metal matrix composite.

31. A substrate for packaging a semiconductor wherein at least a portion of the substrate comprises:
(a) constraining metal matrix composite having a first and a second side, the metal matrix composite comprising a copper/refractory metal composite having a composition of approximately between 50 wt. % and 95 wt. % refractory metal;
(b) a first carrier layer comprising a metal matrix composite having a thermal expansion and thermal conductivity greater than the constraining metal matrix composite and attached to the first side of the constraining metal matrix composite; and
(c) a second carrier layer comprising a metal matrix composite having a thermal expansion and thermal conductivity greater than the constraining metal matrix composite and attached to the second side of the constraining metal matrix composite.

32. The substrate of claim 31 wherein the refractory metal is selected from a group consisting of tungsten, molybdenum, chromium, niobium, tantalum, vanadium, titanium.

33. The substrate of claim 31 wherein the refractory metal comprises 85 wt. % tungsten so as to form a copper/tungsten composite having copper 15 wt. % and tungsten 85 wt. %.

34. The substrate of claim 31 wherein the refractory metal comprises 85 wt. % molybdenum so as to form a copper/molybdenum composite having copper 15 wt. % and molybdenum 85 wt. %.

35. The substrate of claim 33 wherein the metal matrix composite of the first carrier layer comprises a higher wt. % of copper than the constraining layer.

36. The substrate of claim 31 wherein the first carrier layer comprises vias.

37. The substrate of claim 31 wherein the second carrier layer comprises vias.

38. A substrate for packaging a semiconductor wherein at least a portion of the substrate comprises:
(a) a beryllia/beryllium composite having a first and a second side;
(b) a first carrier layer having a coefficient of thermal expansion and thermal conductivity greater than the beryllia/beryllium composite and attached to the first side of the composite; and
(c) a second carrier layer having a coefficient of thermal expansion and thermal conductivity greater than the beryllia/beryllium composite and attached to the second side of the composite.

39. The substrate of claim 37 wherein the first carrier layer comprises copper.

40. The substrate of claim 37 wherein the second carrier layer comprises copper.

41. The substrate of claim 37 wherein the beryllia/beryllium composite comprises a 20-60 vol. % beryllia.

42. A substrate for packaging a semiconductor wherein at least a portion of the substrate comprises:
(a) an aluminum/silicon carbide composite having a first and a second side;
(b) a first carrier layer having a coefficient of thermal expansion and thermal conductivity greater than the aluminum/silicon carbide composite and attached to the first side of the composite; and
(c) a second carrier layer having a coefficient of thermal expansion and thermal conductivity greater than the aluminum/silicon carbide composite and attached to the second side of the composite.

43. The substrate of claim 42 wherein the aluminum/silicon carbide composite comprises 55 to 75 vol. % silicon carbide.

44. A method of making a substrate for a semiconductor package comprising the steps of:
(a) providing a 50 wt. % to 95 wt. % refractory metal matrix composite;
(b) attaching a first material having a coefficient of thermal expansion and thermal conductivity higher than the metal matrix composite to a first side of the metal matrix composite; and
(c) attaching a second material having a coefficient of thermal expansion and thermal conductivity higher than the metal matrix composite to a second side of the metal matrix composite.

45. The method of claim 44 wherein step (b) comprises the step of placing a first brazing preform on the first side of the metal matrix composite.

46. The method of claim 45 wherein step (c) comprises the step of placing a second brazing preform on the second side of the metal matrix composite.

47. The method of claim 45 wherein step (b) further comprises the step of contacting the first carrier layer with the first brazing preform.

48. The method of claim 46 wherein step (c) further comprises the step of contacting the second carrier layer with the second brazing preform.

49. The method of claim 46 further comprising the step of heating the substrate at a temperature of approximately between 280° C. and 900° C.

50. The method of claim 44 further comprising the step of attaching a ceramic window layer on the first carrier layer.

51. A method of making a substrate for a semiconductor package comprising the steps of:
(a) providing a 50 wt. % to 95 wt. % refractory metal matrix composite;
(b) attaching a first material having a thermal expansion and thermal conductivity higher than the metal matrix composite to a first side of the metal matrix composite via a direct bond copper process; and
(c) attaching a second material having a expansion and thermal conductivity higher than the metal matrix composite to a second side of the metal matrix composite via a direct bond copper process.

52. The method of claim 51 wherein step (b) comprises the step of placing a first copper preform between the first material and the first side of the metal matrix composite.

53. The method of claim 52 wherein step (c) comprises the step of placing a second copper preform between the second material and the second side of the metal matrix composite.

54. The method of claim 53 further comprising the step of heating the substrate to a temperature above 1065° C.

55. The method of claim 51 wherein step (a) comprises the step of providing a 50 wt. % to 95 wt. % tungsten metal matrix composite.

56. The method of claim 51 wherein step (a) comprises the step of providing a 50 wt. % to 95 wt. % molybdenum metal matrix composite.

57. The method of claim 51 further comprising the step of attaching a ceramic window layer to the first layer of material.
